(19) United States
(12) Patent Application Publication
(10) Pub. No.: US 2013/0241075 A1
(43) Pub. Date: Sep. 19, 2013

(54) CONTACT OR VIA CRITICAL DIMENSION CONTROL WITH NOVEL CLOSED LOOP CONTROL SYSTEM IN CHEMICAL MECHANICAL PLANARIZATION PROCESS

(71) Applicants: Chin-Tsan Yeh, Hsinchu City (TW); Chun-Fu Chen, Taipei City (TW); Yung-Tai Hung, Chiayi City (TW); Chin-Ta Su, Yunlin Country (TW)

(72) Inventors: Chin-Tsan Yeh, Hsinchu City (TW); Chun-Fu Chen, Taipei City (TW); Yung-Tai Hung, Chiayi City (TW); Chin-Ta Su, Yunlin Country (TW)

(73) Assignee: MACRONIX INTERNATIONAL CO., LTD., Hsin-chu (TW)

(21) Appl. No.: 13/418,920

(22) Filed: Mar. 13, 2012

(51) Int. Cl. H01L 21/306; H01L 29/30; B24B 49/00

(52) U.S. Cl. 257/774; 451/5; 438/692; 257/E21.23; 257/E29.106

(57) ABSTRACT

Closed loop control may be used to improve uniformity of contact or via critical dimension using chemical mechanical planarization. For example, real-time closed loop control may be used to adjust oxide buffing or over-polishing time in a chemical mechanical planarization process to more uniformly and consistently achieve a target critical dimension of a semiconductor wafer.

### TECHNOLOGICAL FIELD

Embodiments of the present invention relate generally to chemical mechanical polishing (CMP) processes and, more particularly, to the use of closed loop control (CLC) for improved contact or via critical dimension (CD) control.

### BACKGROUND

Since the advent of computers, there has been a steady drive toward producing smaller and more capable electronic devices, such as computing devices, communication devices and memory devices. To reduce the size of such devices, while maintaining or improving their respective capabilities, the size of components within the devices must be reduced. Several of the components within electronic devices are made from semiconductor materials, which in some cases are provided via a structure called a semiconductor wafer.

In recent years, there have been numerous advances related to enhancing the ability of semiconductor device manufacturers to produce semiconductor devices with reduced dimensions. Reductions in semiconductor device dimensions may provide higher densities and improve performance of integrated circuits. In many electronic devices that employ integrated circuits, the integrated circuits may include millions of discrete elements such as transistors, resistors and capacitors that are built in close proximity to each other on a single wafer. In some cases, the close proximity of these elements can create undesirable effects such as parasitic capacitance or other performance degrading conditions. Accordingly, electrical isolation of elements on a common substrate in semiconductor devices is an important part of the fabrication process.

Semiconductor devices include integrated circuits (IC) that have a network of conductive structures that include interconnect lines, contacts and vias. The performance of the semiconductor device is dependent upon well-defined contacts and vias, otherwise known as the contact structures that are formed between interconnection structures of an integrated circuit. Low resistances across these interconnection structures are critical to enhancing the performance of the device. As the size of the contact decreases, which is generally required as the semiconductor devices become smaller, the ability to entirely fill the contact or via openings with conductive material becomes more difficult. Any void space or non-uniform deposition of the conductive material throughout the contact or via openings will result in increased resistance and a deterioration in device performance.

Post-processing techniques following deposition may be employed on an integrated circuit for the purpose of ensuring the device meets certain specifications. Examples of post-processing techniques may include, but are not limited to, optical proximity correction (OPC), resolution enhancement techniques (RET), etch proximity compensation, gap fill compensation, and chemical mechanical planarization (CMP) or tungsten chemical mechanical planarization (W CMP) that specifically processes circuits that use tungsten as a conductor.

Chemical mechanical planarization combines both chemical action and mechanical forces to remove metal and dielectric overlayers, for example, in damascene processes, to remove excess oxide in shallow trench isolation steps, and to reduce topography across a dielectric region. Components required for chemical mechanical planarization typically include a chemically reactive liquid medium in the form of a slurry and a polishing surface to provide the mechanical control required to approach planarity. The slurry may contain abrasive inorganic particles to enhance the reactivity and mechanical activity of the process. Typically, for dielectric polishing, the surface may be softened by the chemical action of the slurry, and then removed by the action of the particles.

In a chemical mechanical planarization process, a wafer is affixed to a wafer carrier using back pressure. The wafer is polished by contacting it with a rotating polishing pad. The slurry is applied as the platen rotates. The number of wafers that may be simultaneously processed varies depending upon the design of the platen.

The chemical mechanical planarization process removes excess material from a dielectric layer to achieve a desired critical dimension of, for example, the contact or vias at each layer. An integrated circuit typically has multiple dielectric layers whereby chemical mechanical planarization or polishing follows the metallization step for each of the layers. However, due to variations in existing processing techniques, precise critical dimension control that maintains a high rate of wafer throughput is difficult to achieve.

Due to the variations due to the mechanical nature of a chemical mechanical planarization process, wafer uniformity in a single wafer may be difficult to achieve. For example, a polishing rates at the center of the wafer may differ from those experienced close to the edge of the wafer. There is a need in the art for an improved system, process or method to achieve improved uniformity and consistency in contact or via critical dimension while maintaining or even increasing processing throughput.

Because of the inconsistencies in contact or via critical dimensions related to post-processing a batch of wafers, it is typical to preprocess wafers and adjust the processing parameters as needed to achieve desired target values. However, this is imprecise, time-consuming, and results to lost production. Additionally, while wafers processed earlier in the batch may achieve desired contact or via critical dimensions, variations in processing later in this batch of wafers are not accommodated and are subjected to off-specification processing. There is a need in the art for more precise control of the extent of polishing in a chemical mechanical planarization process and improved wafer uniformity across a batch of wafers that are processed.

As post processing becomes more commonplace, particularly as integrated circuits continue to be reduced in size, consistently maintaining critical dimension of the contacts and vias using these techniques increasingly becomes important. Accordingly, it may be desirable to provide an improved system, process or method for contact or via critical dimension control.

### BRIEF SUMMARY OF EXEMPLARY EMBODIMENTS

Embodiments of the present invention are therefore provided that may provide for improved control of finishing tool to more uniformly achieve a desired property attribute of an integrated circuit such as a wafer.

An aspect of the invention provides a system for finishing a wafer comprising a control model, a finishing tool, and at least one metrological device. The control model is configured to receive a property attribute of the wafer, which is measured by the at least one metrological device, in determining at least one control parameter of the finishing tool.

In an exemplary embodiment of the invention, the finishing tool may be a chemical mechanical planarization tool. Further to this embodiment, the property attribute may be a contact or via critical dimension of the wafer.

In certain embodiments of the invention, the at least once control parameter may be a polishing recipe. The polishing recipe, for example, may be either or both of an oxide buffing time and an over-polishing time.

The property attribute of the wafer may be a property attribute for the wafer prior to finishing the wafer and/or a property attribute for the wafer following finishing of the wafer.

In certain embodiments of the invention, the property attribute may be a metal thickness or a dielectric film thickness in a semiconductor device.

An aspect of the invention provides a method for finishing a wafer comprising specifying a target of a property attribute for the wafer, determining at least one control parameter for a finishing tool using a control model provided with the target of the property attribute; setting the at least one control parameter for the finishing tool, and finishing the wafer using the finishing tool.

In certain embodiments, the finishing tool is a chemical mechanical planarization polishing operation. In certain embodiments, the property attribute is a contact or via critical dimension.

The method may further comprise measuring the property attribute of the wafer at least one of prior to finishing the wafer and after finishing the wafer, and providing the property attribute to the control model for use in determining the at least one control parameter.

It is to be understood that the foregoing general description and the following detailed description are exemplary, and are not intended to limit the scope of the invention.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1A illustrates a cross section of a contact or via profile of an integrated circuit showing top rounding before the application of tungsten chemical mechanical planarization;

FIG. 1B illustrates a transmission electron microscopy contact or via profile of an integrated circuit showing how much tungsten oxide removal is necessary to achieve a desired critical dimension;

FIG. 2A illustrates a transmission electron microscopy contact or via profile showing critical dimension after 60 seconds of tungsten chemical mechanical planarization polishing;

FIG. 2B illustrates a transmission electron microscopy contact or via profile showing critical dimension after 80 seconds of tungsten chemical mechanical planarization polishing;

FIG. 3 illustrates a graphic representation showing the effect of oxide buffing time on the contact or via critical dimension;

FIG. 4 illustrates a graphic representation showing the effect of tungsten over-polishing time on the contact or via critical dimension; and

FIG. 5 is an illustration of a closed loop control diagram employed in an exemplary embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a contact or via” includes a plurality of such contacts or vias.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “critical dimension” refers to the dimension of the smallest geometrical features that can be formed during semiconductor manufacturing. The extent of critical dimension may be purely defined, for example, exclusively by the lithographic process. However, the crux of the present invention is further reducing the critical dimension while consistently maintaining the reduced critical dimension using improved post-processing techniques.

As used herein, “chemical mechanical planarization” (CMP) is a process for smoothing surfaces using the combination of chemical activity and mechanical forces. CMP, otherwise also known as a polishing process, may be used to further refine the finished structural features of an integrated circuit. Chemical mechanical planarization or polishing may be a hybrid process that includes chemical etching and some form of polishing. For example, chemical mechanical planarization can encompass processes that use of abrasive and/or corrosive chemical slurries such as colloidal suspensions in conjunction with a polishing pad. More specifically, a tungsten chemical mechanical planarization process (W CMP) is directed specifically to post-processing treatment of integrated circuits that use tungsten, for example, in contacts or vias for connecting transistors and interconnecting layers.

As used herein, “finishing” means performing a post-processing operation on a wafer. A finished wafer is intended to mean a wafer that has been subjected to the post-processing operation and does not necessarily mean a wafer that has completed manufacturing in all respects. In a non-limiting example, finishing means polishing a wafer to achieve a desired contact or via critical dimension. The wafer may continue to undergo additional metallization and subsequent polishing operations after completion of this finishing operation on the wafer.

The inventors have conceived of and have developed systems and methodologies for control for performing closed loop control of contact or via critical dimension in integrated circuits. In particular, the inventors have conceived of and developed systems and methodologies for controlling the parameters of a chemical mechanical planarization tool to achieve a desired target for contact or via critical dimension in integrated circuits.

The inventors have discovered that it is possible to further reduce contact or via critical dimension by integrating real time closed loop control techniques with the chemical mechanical planarization process for integrated circuit finishing. The systems and methods conceived by the inventors include a closed loop control system combined with methodologies to consistently achieve a desired critical dimension utilizing a chemical mechanical planarization polishing tool. Embodiments of the invention enable real-time critical dimension control by adjusting, for example, tungsten chemical mechanical planarization over-polishing time to achieve a more desirable, accurate, and uniform contact or via critical dimension.

As integrated circuits become smaller, embodiments of the inventive system and inventive method enable a target contact or via critical dimension to be consistently met without compromising throughput. Indeed, according to certain embodiments of the inventive system and inventive method, target contact or via critical dimension may be consistently met while increasing device throughput. According to certain embodiments of the inventive system and inventive method, contact or via critical dimensions were further decreased over those contact or via critical dimensions achieved using systems and methods of the prior art.

A wafer polishing process including, for example, an abrasive trapped or abrasive mounted pad may be controlled using the inventive techniques to provide improved uniformity of contact or via critical dimension. A method of controlling the polishing of a semiconductor wafer may include employing a topologically selective slurry and/or an abrasive trapped pad or abrasive mounted pad in an initial or first polishing operation and controlling, for example, the over-polishing time of a chemical mechanical planarization process in response to feedback measurements of critical dimension for polished wafers.

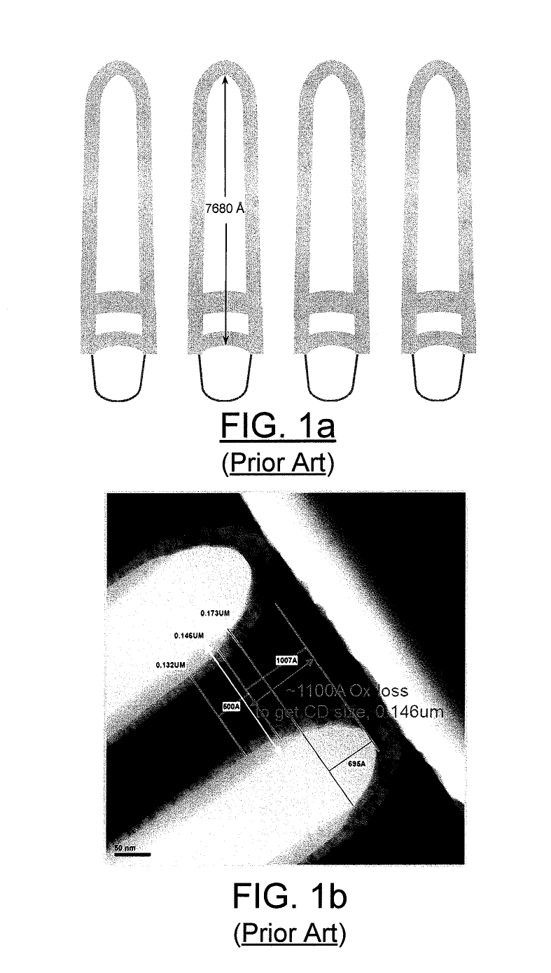

FIG. 1A shows a cross section of a contact or via profile of an integrated circuit showing top rounding before the application of tungsten chemical mechanical planarization. FIG. 1A illustrates top rounding, which is routinely observed in integrated circuits that have not undergone any post-processing. FIG. 1B illustrates that a desired 0.146 μm critical dimension in a contact or via profile could be achieved only after about 1100 Å tungsten oxide removal. Hence, according to FIGS. 1A and 1B, a reduced critical dimension can only be attained by use of a post-processing technique such as, for example, tungsten chemical mechanical planarization.

Contact or via critical dimension may be influenced by a number of process parameters in the chemical mechanical deposition process including but not limited to, for example, polishing speed, pressure, slurry characteristics, extent of slurry addition, and polishing profile which may include oxide buffing time, and over-polishing time as variables to be controlled in the chemical mechanical deposition pressure.

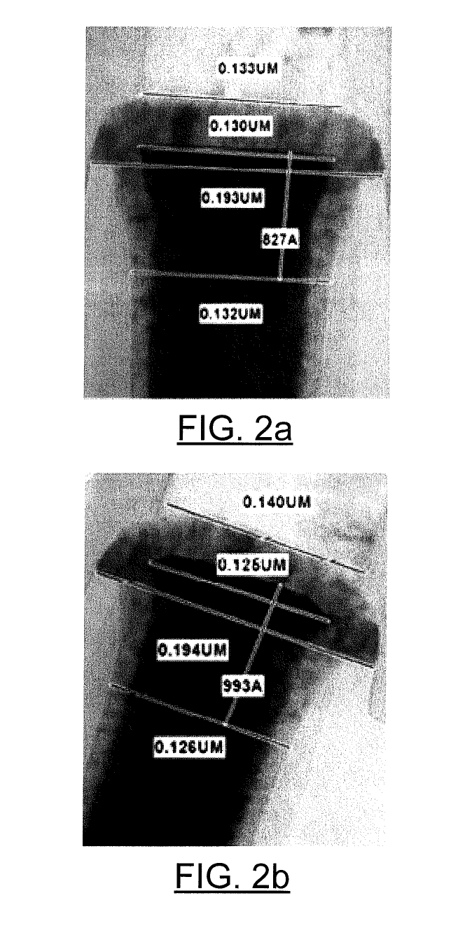

FIGS. 2A and 2B illustrate a transmission electron microscopy contact or via profile after subjecting the integrated circuit to 60 seconds and 80 seconds oxide buffing, respectively, at 2 psi applied polishing pressure. As these figures illustrate, the contact top critical dimension experiences a reduction from about 0.130 μm to about 0.125 μm with an additional 20 seconds of oxide buffing at 2 psi applied polishing pressure.

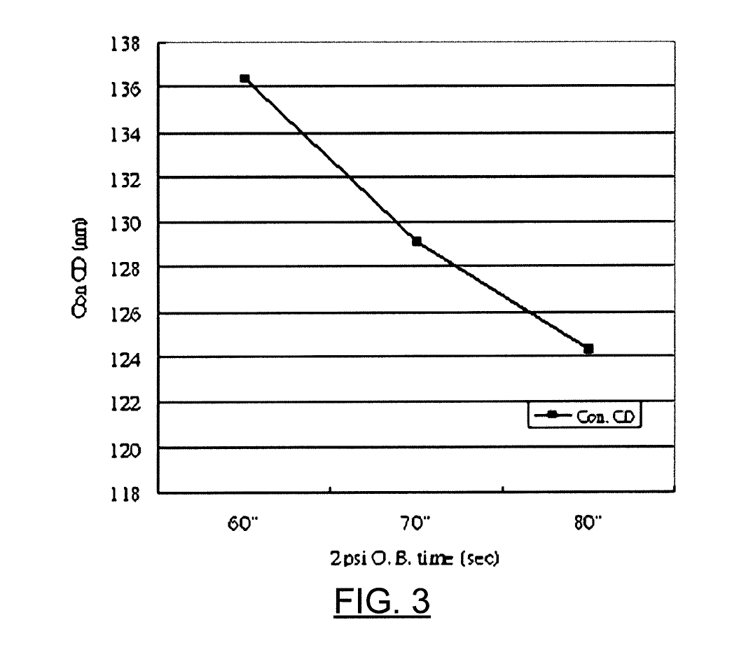

In one exemplary embodiment, FIG. 3 illustrates a graphic representation showing the effect of oxide buffing time on the contact or via critical dimension. Although various different controlled variables including a combination of controlled variables in a multivariable closed loop control system or method may be employed in connection with certain embodiments of the present invention, one example control variable is shown in the illustration of FIG. 3, which shows exemplary data for the extent of reduction in contact or via critical dimension corresponding to the oxide buffing time. Thus, as represented by FIGS. 2A, 2B, and 3, oxide buffing time may be a controlled variable that allows a desired contact or via critical dimension of an integrated circuit to be achieved.

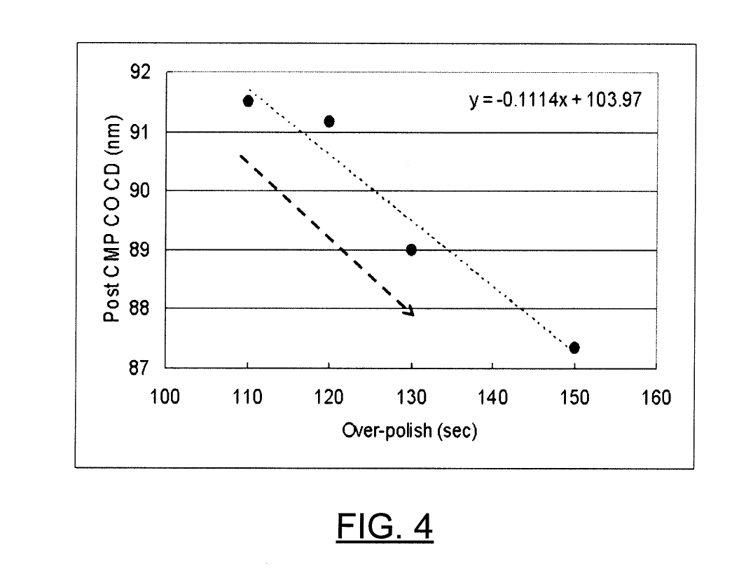

In another exemplary embodiment, FIG. 4 illustrates a graphic representation showing the reduction in contact critical dimension for varying over-polishing time. Thus, as represented by FIG. 4, over-polishing time may be a controlled variable that allows a desired contact or via critical dimension of an integrated circuit to be achieved.

Notably, the graphical representations of FIGS. 3 and 4 may be affected by many factors including, but not limited to, variability in the processes leading to the unfinished integrated circuit (e.g., mask error, hazing effects, etc.), variability in the materials used in the deposition process, differences in layout and topography, wear of the polishing pad, inconsistency of the slurry, variations in diffusional or transport rates due to inconsistencies of metallization or slurry materials, and environment effects in the production cycle, as well as other factors.

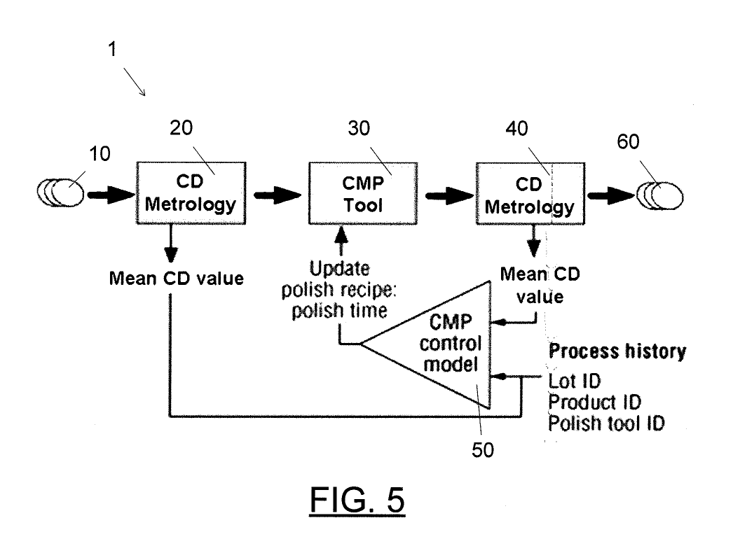

Some embodiments of the present invention may provide improvements in the control of contact or via critical dimension or more generally to metal or dielectric film thickness in semiconductor devices. In this regard, FIG. 5 provides an exemplary representation of an embodiment showing a closed loop control diagram using a control model of the invention for control of the contact or via critical dimension, which may also be extended to control of a metal or dielectric film thickness.

The critical dimension of wafers to be processed may be measured by a measurement device and the required removal rate may be calculated for each polishing head as the wafers are being processed. The prediction of polishing time may be based upon, for example, the most recent removal rate, the critical dimension of wafers to be processed, and the targeted critical dimension for the polished or finished wafers. The controller then may feedback information for the next wafers to be polished. The process control system results in improvement of the uniformity for all processed wafers.

The closed loop control diagram 1 represented in FIG. 5 shows the unfinished wafers 10 that are to be subjected to post-processing using, for example, a chemical mechanical planarization process. The contact or via critical dimension of the unfinished wafers 10 may undergo a pre-finishing critical dimension metrology 20 or measurement system or device to provide the closed loop controller or closed loop control procedure with information concerning the extent of finishing or polishing the unfinished wafers 10 may need to be subjected to.

Feedforward and feedback of a measured critical dimension using some metrological or measurement device allows for the closed loop control system to compensate for any errors in predictive measurement. Examples of metrological devices include, but are not limited to, atomic force microscopy (AFM), scanning force microscopy (SFM), scanning tunneling microscopy (STM), nearfield scanning optical microscopy (NSOM), scanning electron microscopy (SEM), transmission electron microscopy (TEM), low energy electron diffraction (LEED), field emission microscopy (FEM), and field ionization microscopy (FIM).

AFM and SFM techniques probe the surface of the integrated circuit with a sharp tip. The deflections encountered by the tip as it probes the surface allow a computer to generate a map of the surface topography including critical dimension values.

STM involves scanning the surface of the integrated circuit using a sharp conducting tip that measures the tunnel current between the surface and the tip to gather information on surface topography.

NSOM integrates optical microscopy with scanning probe techniques. The tip of the probe transmits light to the surface whose intensity collected and recorded with respect to the position of the probe.

SEM employs a scanning electron beam across the surface of an integrated circuit. Detection of secondary low energy or backscattered electrons allow for generation of a surface profile and structure, composition, and crystallographic information.

TEM uses a high energy electron beam for high resolution imaging in integrated circuit samples.

LEED is used to detect symmetry and atomic arrangement of solid crystal surfaces and thin films by impinging low energy electrons onto the surface and detecting the diffraction pattern on a screen.

FEM and FIM employ the use of a metal tip in either a vacuum or inert atmosphere to either detect emitted electrons or ionized gas particles that develop at the surface.

The mean critical dimension information provided by the pre-finishing critical dimension metrology 20 is directed to the chemical mechanical planarization control model 50 to be used to provide feedforward compensation based upon the characteristics of the unfinished wafers 10 that will be subjected to post-processing in the chemical mechanical planarization tool 30.

While model-based controllers have been employed in other art segments, they have not gained widespread use in integrated circuit processing. For example, model-based controllers employing linear and/or non-linear control methods have been more common in the continuous process industries, but have not gained acceptance in the discrete time processing industries.

A control model utilizes model structures and model parameters to determine the required adjustments to at least one controlled variable of a process to correct for deviations between a measured value of a variable and the desired target value for that variable. These models may include, but are not limited to, linear and/or non-linear dynamic models. The models may be, for example, single or multivariable models. These control models may be capable of adaptation to accommodate changes to any number of factors such as, for example, non-linearity in the models, model error, measurement error, etc. Model adaptation may accommodate changes in production rate or targets, for example, or may be varied depending upon response times of the various types of production equipment.

The input variables to the model may be measured or inferred and may be provided in real-time and/or discretely entered such as, for example, data that may be held in a database or manually derived. Dynamic models, in particular, are well-suited for processes and/or measurement devices having time delay or varying response times due to factors such as changes in production rate or oxide removal rate, for example.

The chemical mechanical planarization control model 50 may determine a polishing recipe providing, for example, a polishing time to the chemical mechanical planarization tool 30. The polishing time may be the amount of oxide buffing time using model-based characteristics that oxide buffing time has relative to the extent of contact or via critical dimension reduction similar to a relationship established by, for example, FIG. 3 or the amount of over-polishing time using model-based characteristics that over-polishing time has relative to the extent of contact or via critical dimension reduction similar to a relationship established by, for example, FIG. 4. These adjustments to the chemical mechanical planarization tool 30 will be made by the chemical mechanical planarization control model 50 to achieve a target contact or via critical dimension for the finished polish wafers 60.

The processed wafers exit the chemical mechanical planarization tool 30 and may again be subjected to a post-finishing critical dimension metrology 40 or measurement system or device to provide the chemical mechanical planarization model 50 with information concerning the extent of reduction of the contact or via critical dimension of the wafers leaving the chemical mechanical planarization tool 30. The chemical mechanical planarization control model 50 may use this information in a feedback control scheme to compensate for contact or via critical dimension of the processed wafers that deviate from the contact or via critical dimension predicted by the chemical mechanical planarization control model 50 in an effort to achieve the target contact or via critical dimension of the polished wafers. The chemical mechanical planarization control model 50 may use this information to adjust the polish recipe of the chemical mechanical planarization tool 30 by adjusting certain parameters such as oxide buffing time or over-polishing time as described earlier.

The finished polished wafers 60 exit the process following post-finishing critical dimension metrology 40.

In addition to utilizing information contact or via critical dimension of the unfinished wafers 10 as provided by pre-finishing critical dimension metrology 20 or contact or via critical dimension of the finished polished wafers 60 provided by post-finishing critical dimension metrology 40, the chemical mechanical planarization model 50 may also use process history information in determining the most appropriate model information to use in establishing the polish recipe to provide to the chemical mechanical planarization tool 30. To achieve the targeted contact or via critical dimension of the finished polished wafers 60.

Additionally, the chemical mechanical planarization model 50 may be configured to receive other identifying information such as, for example, lot identification or product identification information to establish the necessary models and/or model parameters to be used in establishing the polish recipe to be implemented by the chemical mechanical planarization tool 30. The chemical mechanical planarization model 50 may also be configured to receive polish tool identification information and select the appropriate control model and/or control model variables depending upon the characteristics of the chemical mechanical planarization tool 30 polishing the wafers.

A system of the invention for finishing a wafer may comprise a control model, in particular, a chemical mechanical planarization control model. The system of the invention may also comprise a critical dimension metrological device for measuring contact or via critical dimension. The control model of the system may be configured as further described herein.

The critical dimension metrological device, according to certain embodiments of the invention, may measure the average contact or via critical dimension of wafers being processed. The system may comprise a pre-finishing critical dimension metrological device, a post-finishing critical dimension metrological device, or any combination thereof.

In other embodiments, the system of the invention comprises a finishing tool for a wafer. For example, in certain preferred embodiments, the wafer finishing tool is a chemical mechanical planarization tool.

The control model may receive a measured property attribute of the wafer from the at least one metrological device and determine at least one control parameter for the finishing tool. In certain other embodiments of the invention, the control model will provide a series of control parameters, such as, for example, a control recipe to be implemented over the course of processing the wafer by the finishing tool.

In certain embodiments of the invention, the control model is configured in a control system and/or a process computer, which collects the information used by the control model that may include, but is not limited to, critical dimension of a wafer or wafers to be finished and/or a wafer or wafers that have been finished; process information for the wafer finishing tool; historical processing information collected, for example, from a database; information concerning the wafers being process such as lot identification or product information; and/or performance information for the wafer finishing tool.

As a person having ordinary skill in the art would understand given the benefit of the disclosure, the system of the invention would include other ancillary equipment, instrumentation, software, firmware, etc. as needed to make the system operational for its intended purpose.

A method of the invention comprises, in no particular order, specifying a target of a property attribute for the wafer, determining at least one control parameter for a finishing tool using a control model given the target of the property attribute for the wafer, setting the at least one control parameter of the finishing tool, and finishing a wafer using the finishing tool.

In certain embodiments of the invention, an ordered arrangement of the steps of the method may be preferred. For example, it is typically desired to provide a target for the property attribute of the wafer prior to commencing the finishing step. Furthermore, it may be desired to determine the at least one control parameter of the finishing tool just prior to the start of the finishing operation and providing updates to the at least one control parameter as the finishing operation continues.

In certain embodiments of the invention, the finishing tool is a chemical mechanical planarization tool. Pursuant to certain of these embodiments, the control model is a chemical mechanical planarization control model and the at least one control parameter comprises a polishing recipe. The property attribute, according to certain embodiments of the invention, may be a contact or via critical dimension.

The method of the invention may further include measuring the property attribute of the wafer. According to various embodiments of the invention, the property attribute may be measured for the wafer prior to finishing the wafer, after finishing the wafer, or any combination thereof. According to these embodiments, the method of the invention may further comprise, providing the at least one measured property attribute of the wafer to the control model for determining the at least one control parameter.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A system for finishing a wafer comprising:
a control model;
a finishing tool; and
at least one metrological device,
wherein the control model receives a property attribute of the wafer measured by the at least one metrological device and determines at least one control parameter of the finishing tool.

2. The system of claim 1, wherein the finishing tool is a chemical mechanical planarization tool.

3. The system of claim 2, wherein the property attribute is a contact or via critical dimension.

4. The system of claim 2, wherein the at least one control parameter comprises a polishing recipe.

5. The system of claim 4, wherein the polishing recipe comprises at least one of an oxide buffing time and an over-polishing time.

6. The system of claim 1, wherein the property attribute is at least one of a property attribute for the wafer prior to finishing and a property attribute for the wafer following finishing.

7. The system of claim 1, wherein the property attribute is a metal thickness or a dielectric film thickness.

8. A method for finishing a wafer, comprising:
specifying a target of a property attribute for the wafer;
determining at least one control parameter for a finishing tool using a control model provided with the target of the property attribute;
setting the at least one control parameter for the finishing tool; and
finishing the wafer using the finishing tool.

9. The method of claim 8, wherein the finishing tool is a chemical mechanical planarization tool.

10. The method of claim 9, wherein the property attribute is a contact or via critical dimension.

11. The method of claim 9, wherein the at least one control parameter comprises a polishing recipe.

12. The method of claim 11, wherein the polishing recipe comprises at least one of an oxide buffing time and an over-polishing time.

13. The method of claim 8, further comprising
measuring the property attribute of the wafer at least one of prior to finishing the wafer and after finishing the wafer; and
providing the property attribute to the control model for use in determining the at least one control parameter.

14. A wafer for a semiconductor prepared by a process comprising:
specifying a target of a property attribute for the wafer;
determining at least one control parameter for a finishing tool using a control model provided with the target of the property attribute;
setting the at least one control parameter for the finishing tool; and
finishing the wafer using the finishing tool.

15. The wafer of claim 14, wherein the finishing tool is a chemical mechanical planarization tool.

16. The wafer of claim 15, wherein the property attribute is a contact or via critical dimension.

17. The wafer of claim 14, wherein the at least one control parameter comprises a polishing recipe.

18. The wafer of claim 17, wherein the polishing recipe comprises at least one of an oxide buffing time and an over-polishing time.

19. The wafer of claim 14, wherein the property attribute is at least one of a property attribute for the wafer prior to finishing and a property attribute for the wafer following finishing.

20. The wafer of claim 14, wherein the property attribute is a metal thickness or a dielectric film thickness.
